(19) United States
(12) Patent Application Publication
(10) Pub. No.: US 2024/0256747 A1
(43) Pub. Date: Aug. 1, 2024

(54) STATEMENT BLOCK ENCAPSULATION METHOD AND APPARATUS, ELECTRONIC DEVICE, AND STORAGE MEDIUM

(71) Applicant: SHANGHAI GUOWEI SILCORE TECHNOLOGY CO., LTD., Shanghai (CN)

(72) Inventors: Zhongwei Shao, Shanghai (CN); Jifeng Zhang, Shanghai (CN)

(21) Appl. No.: 18/565,473

(22) PCT Filed: Oct. 27, 2021
(86) PCT No.: PCT/CN2021/126677

§ 371 Date: Nov. 29, 2023

(30) Foreign Application Priority Data
Jun. 1, 2021 (CN) 202110606072.0

(51) Int. Cl. G06F 30/327; G06F 8/41

(52) U.S. Cl. CPC G06F 30/327; G06F 8/427

(57) ABSTRACT

Embodiments of the present description provide a statement block encapsulation method and apparatus, an electronic device, and a storage medium, being applied to the technical field of electronic design automation. The encapsulation method comprises: according to a segmentation boundary obtained by an RTL segmentation tool, determining a plurality of statement blocks to be encapsulated; traversing each statement block to be encapsulated, wherein a module where the current statement block to be encapsulated is located is used as the current processing module; and scanning the current processing module, determining whether the current processing module comprises a black box signal, and according to the black box signal, clustering a sub-module and the statement block to perform encapsulation processing. The black box signal is used as a bond to perform encapsulation processing, so that the RTL segmentation tool is suitable for performing encapsulation processing on the sub-modules and the statement blocks under different syntax rules, improving the processing efficiency, and achieving fast layout planning.

### TECHNICAL FIELD

The present invention relates to the technical field of electronic design automation, and in particular, to a statement block encapsulation method and apparatus, an electronic device and a storage medium.

### BACKGROUND ART

The function of the RTL (Register Transfer Level) segmentation tool is to segment a user's chip logic design code into several parts of code, which are respectively run on different FPGA (Field Programmable Gate Array). The FPGA communicates with each other via interconnection lines, and the FPGA can perform parallel synthesis and logic verification. Here, the processing flow of the RTL segmentation tool roughly includes determining a segmentation boundary, encapsulating a statement block, forming a graph structure, having a graph segmentation, and transferring the graph segmentation result back to the RTL language, so as to facilitate an integration tool to perform logic integration, layout and routing and other processing on each part of the RTL.

When the RTL segmentation tool is used for segmentation, it is required that the segmentation result shall not change the logic designed by the user, and it is also required to change the content and hierarchy of the user's original code as little as possible, as well as to be capable of restoring the user's original code according to the segmentation result.

According to the existing solution, the syntax structure of statement block is scanned directly, the input and output port signals are analyzed and extracted, and the segmented code is encapsulated according to the extracted signals.

However, when a statement block containing a composite structure is encountered, such as a statement block containing a composite structure such as interface/package/struct, it is necessary to go deep into these structures, and search and analyze the syntax and signals thereof. The internal structure of these composite structures is particularly complicated, the number of syntax types involved is extremely large, and a dedicated syntax parsing library needs to be constructed to match all syntax rules so as to ensure correct parsing.

In addition, after these statement blocks with complex structures are encapsulated into new modules, the code form and writing of the new modules are different from the original design of the user, and the code change of the new module is irreversible, which is contrary to the RTL segmentation tool requiring that the modification of the original code of the user be minimized in the area outside the segmentation boundary module.

Therefore, there is a need for a new solution for encapsulating RTL segmentation statement blocks.

### SUMMARY OF THE INVENTION

In view of the above, the embodiments of the present specification provide a statement block encapsulation method and apparatus, an electronic device and a storage medium, which improve the processing efficiency of a RTL segmentation tool and realize fast layout planning.

The embodiments of the present description provide the following technical solutions.

The present description provides a statement block encapsulation method, comprising: determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

The present specification also provides, in an embodiment, a statement block encapsulation apparatus, comprising:
a determination module configured for determining a plurality of statement blocks to be encapsulated according to a segmentation boundary obtained by an RTL segmentation tool;
a traversal module configured for traversing each statement block to be encapsulated, wherein a module where a current statement block to be encapsulated is located is used as a current processing module;
a merging module configured for scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

The present description also provides, in an embodiment, an electronic device for statement block encapsulation, comprising:
at least one processor, and a memory communicatively coupled to the at least one processor;
wherein the memory stores instructions executable by the at least one processor to enable the at least one processor for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

The embodiments of the present description also provide a computer storage medium for statement block encapsulation. The computer storage medium stores computer-executable instructions configured for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering the statement block comprising the black box signal in the current processing module into a first module, and instantiating and updating the first module into the current processing module so as to replace the statement blocks comprising the black box signal in the current processing module; if the current processing module does not comprise a black box signal, scanning each statement block to be encapsulated in the current processing module, extracting port information, clustering each statement block to be encapsulated into a second module according to the extracted port information, and instantiating and updating the second module into the current processing module so as to replace each statement block to be encapsulated in the current processing module;
wherein the black box signal comprises a signal of a signal type not supported by the RTL segmentation tool.

Compared with the prior art, the advantageous effects that can be achieved by the above-mentioned at least one technical solution adopted by the embodiments of the present description at least include the followings.

By taking black box signals as clues and links, within the current module, the modules (which may include sub-modules, statement blocks, etc.) related to the black box signals are clustered into larger modules to retrieve the black box signals to the internal signals of new modules, which can avoid recursive search, deeply analyze the internal nested structure of the black-box, and avoid analyzing and extracting the internal signal interconnections, logical relationships and syntaxes. Although the modules are clustered and segmentation boundaries are adjusted, the scope of action of composite structures is usually limited, and the final impact on the segmentation results is small. At the same time, after the encapsulation operation is performed by the encapsulation solution provided in the present description, operations such as signal extraction, encapsulation and clustering in the phase of converting RTL to hypergraph are performed in reverse after obtaining the segmentation result so as to restore the original code and hierarchy of the user, without destroying the source code structure, reducing the risk of introducing errors, and achieving rapid layout planning of the RTL segmentation tool.

### BRIEF DESCRIPTION OF THE DRAWINGS

In order to more clearly illustrate the technical solutions in the embodiments of the present application, the drawings to be used in the description of the embodiments will be briefly introduced below. Obviously, the drawings in the description below are only some embodiments of the present application. It will be apparent to those skilled in the art to obtain other drawings according to these drawings without involving any inventive effort.

FIG. 1 is a structural diagram of a circuit module described in a hardware circuit description language.

FIG. 2 is a schematic diagram of encapsulating a statement block.

FIG. 3 is a structural diagram of a statement encapsulation solution provided by an embodiment of the present specification.

FIG. 4 is a flowchart of a statement block encapsulation method provided by an embodiment of the present specification.

FIG. 5 is a structural diagram before merging and encapsulating between module statements in a statement block encapsulation method provided by an embodiment of the present specification.

FIG. 6 is a structural diagram of creating a new module according to a module statement merged as required in a statement block encapsulation method provided by an embodiment of the present description.

FIG. 7 is a structural diagram for updating a new module obtained by the merging into an original module in a statement block encapsulation method provided by an embodiment of the present specification.

FIG. 8 is a structural diagram of before merging and encapsulating between module statements and statement blocks in a statement block encapsulation method provided by an embodiment of the present specification.

FIG. 9 is a structural diagram of creating a new module according to a statement merged as required in a statement block encapsulation method provided by an embodiment of the present description.

FIG. 10 is a structural diagram for updating a new module obtained by the merging into an original module in a statement block encapsulation method provided by an embodiment of the present specification.

FIG. 11 is a structural diagram of creating a new module according to a plurality of statement blocks as required in a statement block encapsulation method provided by an embodiment of the present specification.

FIG. 12 is a structural diagram for updating a new module obtained by the merging into an original module in a statement block encapsulation method provided by an embodiment of the present specification.

FIG. 13 is a structural diagram before merging and encapsulating between statement blocks in a statement block encapsulation method provided by an embodiment of the present specification.

FIG. 14 is a structural diagram of creating a new module according to a statement block merged as required in a statement block encapsulation method provided by an embodiment of the present specification.

FIG. 15 is a structural diagram for updating a new module obtained by the merging into an original module in a statement block encapsulation method provided by an embodiment of the present specification.

FIG. 16 is a structural diagram of a statement encapsulation apparatus provided by an embodiment of the present specification.

FIG. 17 is a structural diagram of an electronic device for statement block encapsulation provided by an embodiment of the present specification.

### DETAILED DESCRIPTION OF THE INVENTION

The embodiments of this application are described in detail in combination with the accompanying drawings below.

Additional advantages and utility of the present application will become readily apparent to those skilled in the art from the following detailed description, taken in conjunction with the accompanying drawings, illustrating by way of example embodiments of the present application. Obviously, the described embodiments are some, but not all, embodiments of the present application. The present application may be practiced or applied in various other specific embodiments, and the details of the description may be modified or varied from one viewpoint or application without departing from the spirit of the application. It should be noted that the embodiments and the features in the embodiments below may be combined with one another without conflict. Based on the embodiments in the present application, all other embodiments obtained by a person skilled in the art without involving any inventive effort are within the scope of protection of the present application.

It is intended that the following describe various aspects of embodiments within the scope of the appended claims. It should be apparent that aspects described herein may be embodied in a wide variety of forms and that any specific structure and/or function described herein is merely illustrative. Based on the present application, one skilled in the art will appreciate that one aspect described herein can be implemented independently of any other aspects, and that two or more of these aspects can be combined in various ways. For example, the equipment may be implemented and/or a method may be practiced using any number or aspect set forth herein. Additionally, such equipment can be implemented and/or such a method can be practiced using other structure and/or functionality in addition to one or more of the aspects set forth herein.

It should be noted that the figures provided in the following examples merely illustrate the basic idea of the present application in a schematic way. Thus, only the components related to the present application are shown in the drawings instead of being drawn according to the number, shape and size of the components in an actual implementation. In an actual implementation, the type, number and proportion of the components may be changed at will, and the layout of the components may be more complicated.

In addition, in the following description, specific details are provided to facilitate a thorough understanding of the examples. However, it will be understood by those skilled in the art that the aspects may be practiced without these specific details. Furthermore, the terms “first” and “second” are used for descriptive purposes only and are not to be construed as indicating or implying relative importance or implicitly indicating the number of technical features indicated. Thus, a feature defined as “first” or “second” and so on may explicitly or implicitly comprise one or more of the features. In the description of the present invention, unless otherwise specified, the meaning of “a plurality of” is two or more.

Some connection relationships between circuit modules often exist, such as communication, logic control, etc. In a circuit designed using a hardware description language, such as a clock signal, a reset signal, etc. often appear in a plurality of modules, and these signals are also commonly found in statement blocks of assign/always and an instantiation statement to express a simple logic circuit via the statement blocks of assign/always and the instantiation statement, etc. so as to form a complex logic circuit via the simple logic circuit.

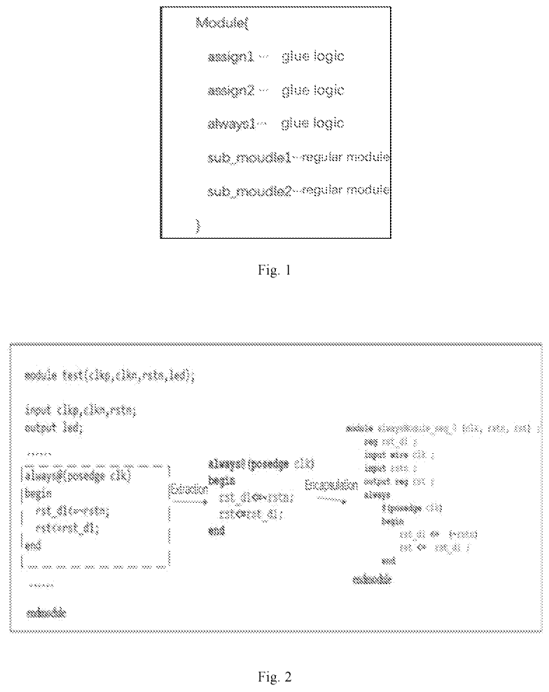

In general, a connection or sequential logic relationship between circuit modules may be referred to as glue logic, where glue logic may be a combinational logic or a sequential logic. As shown in FIG. 1, a typical glue logic in a module may be an assign/always statement block.

In a current RTL segmentation tool, encapsulation often refers to encapsulating non-module code such as an assign/always statement block into a module form, automatically processing the non-module code into a module form, and recording the corresponding relationship between the correct statement blocks and nodes in a graph structure and the connection relationship between nodes based on the formed module. Herein, assign/always refers to a piece of code logic contained in a certain module.

In the existing encapsulation solution, it directly scans the syntax structure of the code block to be encapsulated, and analyze and extract the input and output port signals for encapsulation.

As shown in FIG. 2, when an always statement block located in a certain module (such as an always code block identified by a dashed box in a test module at the left side of the figure) is required to be encapsulated, the always statement block is firstly extracted from the module (such as an identification at the middle part of the figure), then an input/output port signal thereof is analyzed and extracted, and the statement block is encapsulated into a corresponding module form according to the port signal (such as an identification at the right side of the figure).

However, in some syntax rules for hardware description and verification languages, such as the system verilog language, it may be supported to describe circuits in a composite structure. For example, the interior of an assign/always statement block may all contain composite structures such as interface/package/struct. At the same time, the interior of these composite structures may be nested with some structures, such as other complex structures, structures of the same type as the structures themselves, other complex data types such as arrays, enumerations and so on. Namely, there may be several structures nested within the assign/always statement block.

Therefore, in the existing encapsulation solutions, it is required to first enter these statement blocks to extract the input and output signals of all structures, i.e., to go deep into the internal search of complex structures such as interface/package/struct to search and analyze their syntax and signal. It needs to build a dedicated syntax parsing library to match all syntax rules to parse correctly, resulting in the difficulty of encapsulation and slow processing speed.

Also, the segmentation tool is not a syntax parser and is difficult to be able to parse the structural body. In addition, the always/assign statement block can be successfully encapsulated into a new module when it may successfully go deep into the interior of the composite structure and the type, name, and number of input and output signals required for encapsulation can be successfully obtained. However, the deep communication signal obtained through recursive search and deep analysis inside the composite structure (and possibly, the recursive search is required for the nested structure, etc.) will be extracted into the port of new module. This deep signal extraction will irreversibly destroy the structure of user source code. Thus, at the final stage of transition from hypergraph (graph segmentation result) to RTL, the program cannot restore the content and hierarchy of original design according to user source code and segmentation results.

Moreover, it is difficult for the RTL segmentation tool to analyze and process the diverse and diverse grammatical features in languages such as system verilog. Therefore, when faced with the unknown grammatical features, the current segmentation process can only be interrupted, which makes it difficult to correctly extract the input and output signals of the encapsulation module, thus making the whole segmentation process impossible. Furthermore, one of the basic principles of the RTL segmentation tool is that the structural hierarchy and content of the user's non-boundary original code needs to be protected, because the role of RTL segmentation is to help the user segment the logic, rather than modify the code writing method. Thus, by deepening the composite structure and then encapsulating, there may be risks of introducing unexpected syntax errors, breaking the readability of the source code, breaking the design pattern, etc.

Finally, the positioning of RTL segmentation tool is time-consuming and labor-intensive to conduct detailed syntactic analysis in the interior of the composite structure for providing a quick and preliminary layout planning for the user's design, which is not conducive to the rapid segmentation results.

Therefore, the inventors propose a new encapsulation solution for the encapsulation of statement blocks corresponding to segmentation boundaries.

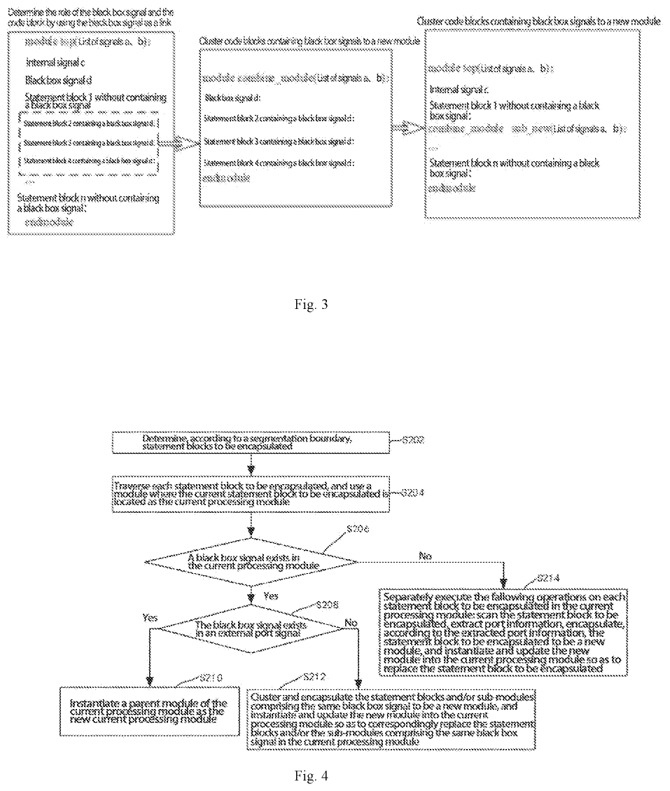

As shown in FIG. 3, in a new encapsulation solution, taking black box signals as clues and links, it is inside the scope of action of the black box signal (which may be referred to as a current processing module (namely, a module)), for example, the scope of action of the black box signal d is only inside the top module, and then a code functional block (where the code functional block may include a statement for instantiating a sub-module and/or a statement block such as always/assign) related to the black box signal, for example, statement blocks 2 to 4, may be clustered and encapsulated into a new module, for example, a combine_module, so as to retract the black box signal into the internal signal of the new module, which may avoid recursive search and in-depth analysis of the internal nested structure of the statement block containing the black box signal, and avoid analyzing and extracting the interconnection and logical relationships, syntaxes, etc. of the internal signal.

It should be noted that, in the top module shown in the figure, other non-black-box signals, such as an internal signal c, if the internal signal c is only used by a statement block 2, a statement block 4, etc., the internal signal c may also be put into the new module, combine_module in a same manner as a black box signal d when the statement block 2 and the statement block 4 are encapsulated as a new module. If the internal signal c is used by other statement blocks in addition to the statement block 2 and the statement block 4, the internal signal c should be left in the top module and be declared in the port of the new module, combine_module, which will not be described in detail in the following description.

It should be noted that, in the top module shown in the figure, since other statement blocks to be encapsulated do not contain a black box signal, for example, the statement block 1 does not contain a black box signal, they may be independently encapsulated into a new module, and the statement block is correspondingly replaced with the encapsulated new module, which will not be described in detail in the following description.

It should be noted that the black box signal may include a signal of a signal type which is not supported by the RTL segmentation tool, such as a signal of a composite structure signal type, or a signal of a signal type which does not have a corresponding parsing rule and can be parsed. By processing these signals as the black box signals, it is not necessary to enter the inside of statement blocks (such as a composite structure) containing the black box signal for recursive search, and go deep into a nested structure for parsing and signal extraction during encapsulation, but to cluster the statement blocks related to these black box signals to form a new module so as to complete statement block encapsulation.

Herein, the composite structure may include a structure body composed of a composite structure signal type supported by a syntax rule of a certain language, for example, a composite structure signal type (such as interface/package/struct, etc.) supported by a system verilog language. The signal types that may be parsed without a corresponding parsing rule may include, for example, signal types that are not listed in a white list library. Herein, the white list library may be built inside a tool, a list of signal types that can be correctly processed in an encapsulation statement block, for example, simple types of signals (such as wire, register, etc.). During the encapsulation, the signal types in the white list may be directly extracted from a port and be encapsulated into a module, without deepening, recursive searching, and analyzing an internal nested structure and syntax thereof. Also, the use of white list library may continue to expand the range of support for complex signal types, such that the larger the white list library, the less black box signals will be encountered. By taking black box signals as clues and links, the statement blocks containing black box signals are clustered into a larger new module, which avoids recursive search into the statement blocks containing black box signals, and deepening the nested structure for syntax analysis and signal extraction. Based on the new module, not only the correct corresponding relationship between statement blocks and nodes and the connection relationship between nodes can be recorded after synthesis and flattening, and then based on the correct corresponding relationship and connection relationship, the nodes can be correctly converted into the RTL language, but also the original code and hierarchy of the user can be restored in reverse. The source code structure is not destroyed, the risk of introducing errors is reduced, and fast layout planning of RTL segmentation tool is realized.

The technical solutions provided by various embodiments of the present application are described below with reference to the accompanying drawings.

As shown in FIG. 4, the embodiments of the present description provide a statement block encapsulation method for encapsulating statement blocks in an RTL segmentation tool, which may include:

step S202, determining a plurality of statement blocks to be encapsulated according to a segmentation boundary obtained by an RTL segmentation tool.

In the implementation, the function of the RTL segmentation tool is to segment the user's chip logic design into a specified number of different parts, respectively running on different FPGA. There are corresponding interconnection lines between the FPGA, so as to facilitate the user to perform parallel synthesis and logic verification of the FPGA. The user logic functions before and after segmentation should remain unchanged, but the code at the segmentation boundary must be changed. Namely, the code logic at the segmentation boundary needs to be cut. Thus the code before cutting needs to be encapsulated. Here, the encapsulation refers to processing the code into the form of module. Only when the statement block is encapsulated into a module form, the corresponding relationship between the correct statement block and the node in the graph structure and the connection relationship between the nodes can be recorded after synthesis and flattening. Only when there is a correct corresponding relationship and connection relationship can the node be correctly converted into the RTL language. On the contrary, if no encapsulation is performed, the corresponding relationship between the statement block and the synthesized netlist will not be found after synthesis, which is equivalent to losing the statement block.

In the implementation, the segmentation boundary can be found by the segmentation boundary search module. Then after the segmentation boundary is found, it can be known which internal sub-modules and statement blocks in the module are required to become nodes in the graph structure to participate in the segmentation, and then it can be known which statement blocks are required to be encapsulated.

Thus, the RTL segmentation tool can determine from each segmentation boundary which statement blocks corresponding to that segmentation boundary need to be encapsulated.

In some embodiments, statement blocks that are within and/or above a boundary may be determined to be statement blocks to be encapsulated.

It should be noted that the statement block herein refers to a grammatically self-contained unit composed of a set of grammatically related code, such as always statement blocks, assign statement blocks, and others in the verilog language.

Step S204, traversing each statement block to be encapsulated, wherein with regard to the current statement block to be encapsulated in the current traversal, the module where the statement block is located is used as the current processing module.

In implementation, each statement block to be encapsulated corresponding to a segmentation boundary may be traversed from the segmentation boundary.

In traversal, a statement block to be encapsulated currently traversed can be quickly obtained in a syntax tree, and a module where the statement block is located is used as a current processing module.

In some embodiments, the module in which the current statement block is located may be determined by parsing.

In the implementation, before determining a statement block to be encapsulated, all the statement blocks to be encapsulated are read into a memory list, for example, reading an original design of a user, namely, user source code, and a syntax instance tree is generated in the memory, so that a module where the statement block is located can be quickly determined according to the syntax instance tree, and each statement block to be encapsulated may also be quickly traversed according to the syntax instance tree.

Step S206, scanning the current processing module and determining whether the current processing module comprises a black box signal, wherein the black box signal comprises a signal of a signal type not supported by the RTL segmentation tool.

If there is a black box signal in the current processing module, Step S208 is performed, otherwise Step S214 is performed.

Step S208, performing corresponding processing according to the hierarchy of the black box signal when it is determined that a black box signal exists in the current processing module.

In the implementation, the external port signal of the current processing module may be traversed firstly so as to determine whether a black box signal exists in the external port signal. If so, Step S210 is executed, namely, the processing of the current processing module is abandoned and the parent module thereof is processed. If not, Step S212 is executed, namely, the current processing module is processed.

Step S210, instantiating a parent module of the current processing module as a new current processing module, so as to abandon processing the original current processing module and process the new current processing module instead.

In the implementation, if a black box signal exists in the port of the current processing module and the internal statement block thereof is to be encapsulated, the connection relationship outside the black box signal module needs to be known, namely, the connection relationship of these black box signals needs to be deeply analyzed. However, the segmentation tool will not be able to process this in actual processing. Therefore, if a black box signal exists in the port of the current processing module, the processing can be switched to instantiate its parent module. Thus, when the parent module is processed, the original module is treated as a black box, i.e., the module name and port list can be seen, but the internal implementation cannot be seen, avoiding that the segmentation tool needs to go deep into the external connection relationship of the black box signal, and the black box signal becomes unable to be processed and the interruption occurs.

Step S212, clustering the statement blocks and/or sub-modules containing the same black box signal into a new module (such as a first module), and instantiating and updating the new module into the current processing module to replace the statement blocks and/or sub-modules containing the black box signal in the current processing module.

In the implementation, after processing the statement blocks and/or sub-modules related to the black box signal, corresponding to other statement blocks to be encapsulated which do not contain the black box signal, the statement blocks may be respectively encapsulated into corresponding new modules in turn, and the new modules correspondingly replace the original statement blocks, which will not be described here.

Step S214, respectively executing each statement block to be encapsulated in the current processing module, including scanning a statement block to be encapsulated, extracting port information of the statement block to be encapsulated, encapsulating the statement block to be encapsulated into a corresponding new module (such as a second module) according to the extracted port information, and instantiating and updating the new module into a current processing module so as to replace the statement block to be encapsulated before encapsulation.

For example, for a plurality of always/assign statement blocks without containing a black box signal, the always/assign statement blocks can be respectively encapsulated into respective new module, and then these always or assign statement blocks can be correspondingly replaced with the new module. When they are encapsulated into a new module, the port information can be extracted according to what input and output signals exist in the statement block such as always/assign and their signal types. A sub-module is newly created and named to contain the logic in this statement block. The input and output are listed as the parameters of the sub-module. It should be noted that a sub-module without containing a black box signal in a port does not need to be re-encapsulated into a new module, i.e., without encapsulation process, since it is a module itself.

Through steps S202 to S214, various statement blocks to be encapsulated are obtained with regard to various segmentation boundaries, and a new module is formed by taking a black box signal as a clue and a link and clustering according to a code hierarchy and structure corresponding to a scope of action of the black box signal. For example, when an external port signal does not contain a black box signal in the current processing module, and only statement blocks and/or sub-modules in the module contain a black box signal, these statement blocks and/or sub-modules containing the same black box signal can be encapsulated into a new module at this moment, and the logic of these statement blocks and/or sub-modules is recorded by the new module. In contrast, the inclusion of a black box signal in the external port signal of the current processing module means that the current processing module has a connection relationship to the outside via a black box signal (such as a composite structure signal). Therefore, the internal signal and syntax of the composite structure can be selected not to be analyzed, namely, the processing of this module is abandoned, and the parent module thereof is processed instead.

By means of the above-mentioned steps, all the statement blocks are processed, namely, in the statement block encapsulation, a black box signal is taken as a clue, which can avoid recursive search and deeply analyzing the internal nested structure of the black box, and avoid analyzing and extracting the internal signal interconnection relationship and logical relationship, and syntaxes. Although it is possible to cluster (namely, aggregate) a larger module, the scope of action of a composite structure is usually limited, and thus the final influence on the segmentation result is small. At the same time, this clustering solution can reversely restore the original code and hierarchy of the user because it does not extract the deep level signal of the black box signal (such as the composite structure) and does not destroy the source code structure.

In some embodiments, in determining whether a black box signal exists in a current processing module, it is firstly determined whether a black box signal exists in external port information of the current processing module, and then scans to determine whether each statement block and sub-module inside the current processing module contains the black box signal, which can improve processing efficiency.

In the implementation, it first traverses the external port signal of the current processing module. If it is not found that the external port signal contains the black box signal after traversing, each statement block and sub-module in the current processing module are scanned to determine whether the current module contains the black box signal.

In some embodiments, when scanning a statement block and a sub-module in a current processing module, a queue may be used to record the scanned black box signal, so as to facilitate subsequent encapsulation processing on each statement block containing a black box signal, and improve processing efficiency.

In an implementation, the statement block encapsulation method may further include the steps of: establishing a black box signal queue, and storing queue element information corresponding to the black box signal in the black box signal queue, wherein the queue element information is used for characterizing signal attributes of the black box signal in the statement blocks and/or sub-modules. It should be noted that the queue element information may be set according to application requirements. For example, the data for characterizing a signal property may include at least one of information such as a signal name, a signal type, a signal direction and a structure body to which the signal belongs.

In some embodiments, a first-in-first-out queue may be used as a black box signal queue, so that subsequent processing may be improved in processing efficiency by processing sequentially according to the order of entry into the queue.

In some embodiments, after a queue is employed, the statement blocks and/or sub-modules containing the same black box signal may be sequentially clustered and encapsulated into a module form by traversing various queue element information in the queue.

In implementation, when a statement block and/or a sub-module containing the same black box signal in the current processing module is clustered and encapsulated to be a new module, it may include: popping and processing elements in a queue one by one, namely, performing clustering and encapsulation processing on the statement blocks and/or sub-modules containing the same black box signal corresponding to the elements by successively popping information of each queue element in the black box signal queue.

In traversing, for the current queue element information, it may perform the steps of: searching each statement block and/or each sub-module in the current processing module, namely, scanning and searching each statement block and/or sub-module in the current processing module; then collecting a statement block and/or a sub-module containing the current queue element information as a statement item, for example, forming a statement item set to be processed by respectively using a statement block and a sub-module containing the same black box signal as a statement item;
performing a merging operation on the collected statement items, namely, performing a merging operation on the statement block and/or sub-module containing the same black box signal to encapsulate same into a new module.

Note that the statement item here can be a statement block and/or a sub-module composed of several statements, etc. The statement item is used for expressing a certain design logic, such as a module instantiation statement for performing sub-module instantiation, such as a statement block for performing logic processing on a signal, such as an always statement block, an assign statement block, etc.

In implementation, the merging operation may be an operation that merges into a new module, such that each statement block and/or sub-module is encapsulated by merging the resulting new module. Thus, the logic of the statement blocks in the graph structure can be properly recorded in subsequent RTL segmentations. Here, the merging operation may include several forms:
(1) merging multiple instantiated sub-modules, namely, merging between modules.
(2) merging several statement blocks expressing logical processing, namely, merging between statement blocks.
(3) merging between sub-modules and statement blocks, i.e., merging between module and statement blocks.

In implementation, the merging rule may include recovering the communication signals with each other and declaring same as internal signals; performing a union operation on other external input and output signals as a port of a new module; judging whether black box signals contained in each other only exist in the new module within the range of the current operation module; if so, recovering the black box signals to the inside of the new module as internal communication signals; and if not, it is the port of the new module.

The following is an exemplary illustration of the above three merging scenarios.

### Example 1: Merging Operation Between Modules

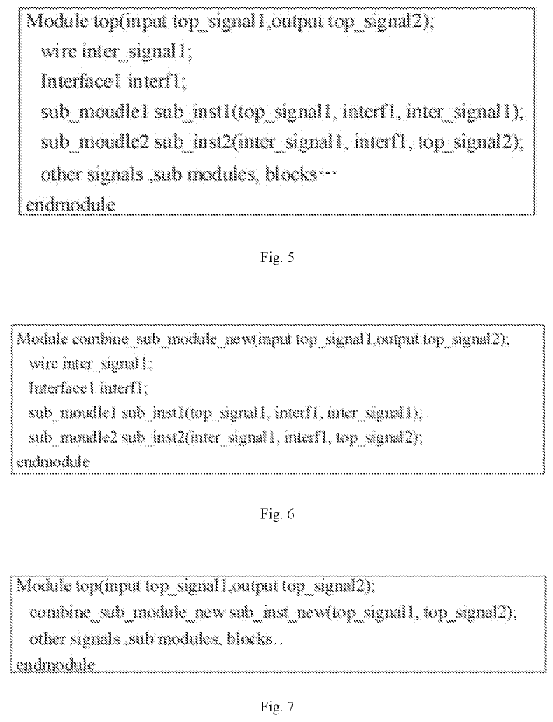

Assuming that the current processing module is a top module as shown in FIG. 5, a merging operation is performed on sub-modules and statement blocks inside the top module before merging. The top module has an input signal top_signal1 and an output signal top_signal2, and the module has an instance interf1 with an internal signal inter_signal1 and a compound structure body (Interface type), two instances of sub-modules using interf1, and other signals, sub-modules and statement blocks.

If interf1 is not used by other sub-modules or statement blocks, it is only used by a sub_module1 and a sub_module2, and inter_signal1 passes signals for the inside of these two module. Therefore, as shown in FIG. 6, according to the merging operation rule, a sub_module1 and a sub_module2 can be merged, namely, the interf1 and inter_signal1 are retracted as internal signals. A merged new module (namely, a new module) is created, and the created new module can be as shown in the figure.

Then, the created new module is updated into the top module, i.e., the top module after the merging operation as shown in FIG. 7.

### Example 2: Merging Between Modules and Statement Blocks

Assuming that the current processing module is a top module as shown in FIG. 8 including an always statement block in which interf1 is used. Thus, the statement block is a complex statement block, and the sub_module1 also uses the interf1. They need to be merged. These are combined as follows.

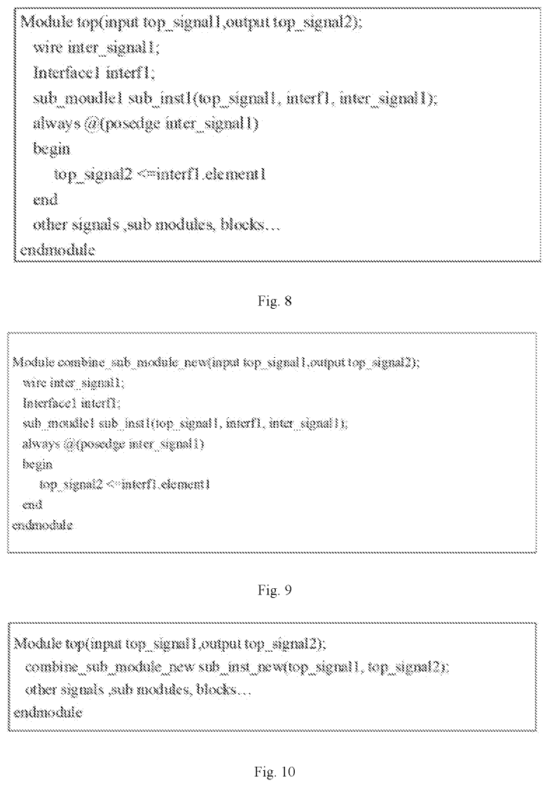

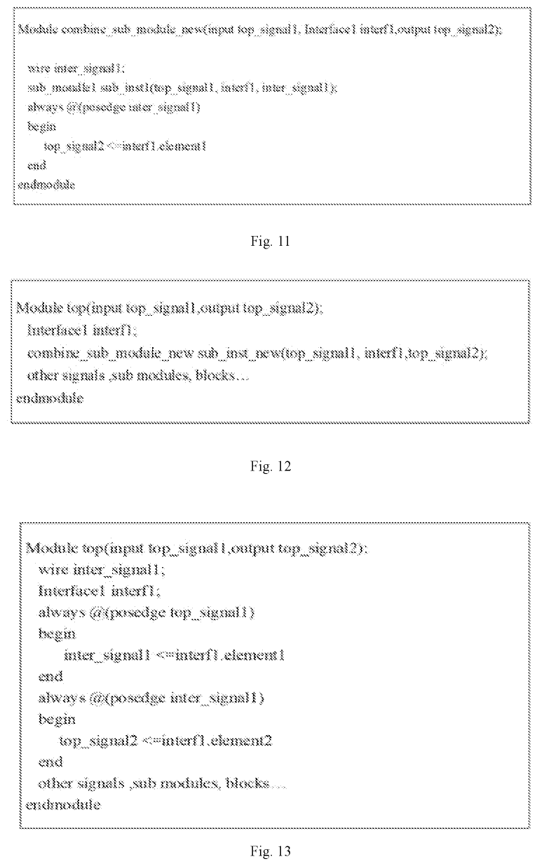

If interf1 is only used by this always statement block and sub_module1, the merged result can be as shown in FIG. 9 and updated to the top module as shown in FIG. 10.

Further, as schematically illustrated in FIGS. 11 and 12, i.e., if interf1 is used by other sub-modules or statement blocks within the top module except the always statement block and sub_module1, this interface should be retained in the port of the new module (i.e., the combine_sub_module_new module in the figure) to complete further merging with other parts until all sub-modules or statement blocks using interf1 have been merged.

### Example 3: Merging Between Statement Blocks

The merging operation between two statement blocks has the same principle as the above two merging cases.

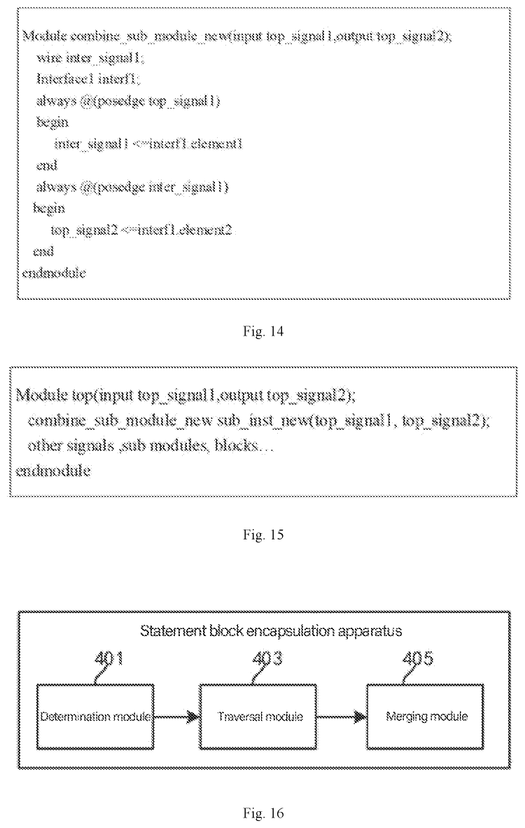

Assuming that interf1 is only used by these two always block, the merging effect is shown in FIGS. 13-15.

Further, if other sub-modules or statement blocks use it, the processing method is similar to that described in Example 2 above, i.e., the port of interf1 is reserved in the new sub-module to be further merged with other relevant parts, and the description will not be expanded.

In some embodiments, a pair-wise combination may be employed in the combining operation, which in turn polymerizes to a larger new module. This may improve processing efficiency.

In implementation, the collected statement items are subjected to a merging operation, which may include:
performing the merging operation on the collected statement items according to pairwise statement items to form a third module; and
instantiating the third module into the current processing module to replace the pairwise statement items prior to the merging.

After the new module is obtained by merging, the statement items before merging are deleted immediately, and then the new module obtained by merging is instantiated and updated into the current processing module to replace the original statement item, so that the logic of the original statement item is recorded by the new module, namely, the logic connotation of the original RTL statement item is recorded.

In some embodiments, since the merging may cause the segmentation boundaries to be adjusted, the segmentation boundaries may be recorded according to the merging process to facilitate subsequent processing of the segmentation boundaries.

In implementation, the statement block encapsulation method may further include: judging whether a statement item of a merging operation is a segmentation boundary; and if so, generating first prompt information which is used for merging the segmentation boundary of the statement item characterizing the merging operation with other statement items.

By recording the situation of segmentation boundary in the encapsulation, the user can be prompted in time, so that the user can understand the adjustment situation of segmentation boundary in the encapsulation process.

In some embodiments, each merging operation may be recorded in the encapsulation to form an operation record for the merging operation.

In implementation, a stack data structure may be used to store the operation record, namely, after each merging operation, the operation record is stored in the stack data structure. Here, the operation record may include an object, an action and port information of the merging operation, so as to facilitate subsequent processing according to the operation record.

In some embodiments, a first-in-last-out stack data structure may be used to store the operation record, which may facilitate reverse operations to restore the content and hierarchy of user source code.

Further, operation records in the stack may be popped in turn during the hypergraph to RTL phase according to the first-in-last-out stack data structure, and the original design code logic, such as the content and hierarchy of the user source code, may be restored by reverse operations.

In some embodiments, in the traversal process, the statement blocks that have been encapsulated to be the new module may be marked as processed, so that unprocessed statement items may be traversed one by one, simplifying processing, and improving processing efficiency.

In some embodiments, the segmentation boundary may be in the current processing module. When processing of the current processing module is abandoned and its parent module is processed, the segmentation boundary should be adjusted accordingly.

In implementation, when the black box signal exists in an external port signal in the current processing module, the statement block encapsulation method may further include generating second prompt information, wherein the second prompt information is used for characterizing moving the segmentation boundary to an upper module.

It prompts the user to adjust the segmentation boundary, so as to avoid cutting the place where the user does not want to cut.

Based on the same inventive concept, the embodiments of the present description also provide a statement block encapsulation apparatus, an electronic device, and a computer storage medium corresponding to the aforementioned encapsulation method.

FIG. 16 is a statement block encapsulation apparatus provided by an embodiment of the present specification.

As shown in FIG. 16, the statement block encapsulation apparatus includes: a determination module 401 configured for determining a plurality of statement blocks to be encapsulated according to a segmentation boundary obtained by an RTL segmentation tool; a traversal module 403 configured for traversing each statement block to be encapsulated, wherein a module where a current statement block to be encapsulated is located is used as a current processing module; and a merging module 405 configured for scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

Optionally, the statement block encapsulation apparatus may further comprise: an instance tree module (not shown in the figure) configured for, before determining statement blocks to be encapsulated according to the segmentation boundary, reading a design code into a memory, and generating a syntax instance tree corresponding to the design code in the memory.

Optionally, the traversing each statement block to be encapsulated includes traversing each statement block to be encapsulated by the syntax instance tree.

Optionally, the scanning the current processing module and determining whether the current processing module comprises a black box signal comprises: traversing an external port signal of the current processing module; and if the external port signal does not comprise the black box signal, scanning whether each statement block and/or sub-module in the current processing module comprises the black box signal.

Optionally, the statement block encapsulation apparatus may further include: a queue module (not shown in the figure) configured for establishing a black box signal queue, and storing queue element information corresponding to the black box signal into the black box signal queue, wherein the queue element information is used for characterizing signal attributes of the black box signal in the statement blocks and/or sub-modules.

Optionally, the structure of the black box signal queue includes a first-in-first-out queue structure.

Optionally, the clustering and encapsulating the statement blocks and/or sub-modules comprising the same black box signal in the current processing module to be a first module includes traversing each piece of queue element information in the black box signal queue, and in the traversal, with regard to the current queue element information, executing the steps of: searching each statement block and/or sub-module in the current processing module, collecting the statement block and/or sub-module containing the current queue element information as statement items, and performing a merging operation on the collected statement items.

Optionally, the performing a merging operation on the collected statement items includes: performing the merging operation on the collected statement items according to pairwise statement items to form a third module; and instantiating the third module into the current processing module to replace the pairwise statement block items prior to the merging.

Optionally, the statement block encapsulation apparatus may further include: a first prompt module (not shown in the figure) configured for judging whether the statement item of the merging operation is a segmentation boundary, and if so, generating first prompt information which is used for merging the segmentation boundary of the statement item characterizing the merging operation with other statement items.

Optionally, the statement block encapsulation apparatus may further include: a first recording module (not shown in the figure) for storing an operation record for each merging operation in a stack data structure, the operation record including an object, an action, and port information for the merging operation.

Optionally, the stack data structure includes a first-in-last-out data structure.

Optionally, the statement block encapsulation apparatus may further include a restore module (not shown in the figure) configured for, in the phase of hypergraph transition to RTL, popping operation records in the stack data structure in turn, and restoring the original design code logic by a reverse operation.

Optionally, the encapsulation apparatus may further include a second recording module (not shown in the figure) configured for, after the encapsulating, according to the extracted port information, the statement block to be encapsulated to be a second module, marking the statement block to be encapsulated which has been encapsulated to be the second module.

Optionally, the statement block encapsulation apparatus may further include: a second prompt module (not shown in the figure) configured for, when it is determined that the black box signal exists in an external port signal in the current processing module, generating second prompt information, wherein the second prompt information is used for characterizing moving the segmentation boundary to an upper module.

Based on the same inventive concept, embodiments of the present specification provide an electronic device for statement block encapsulation.

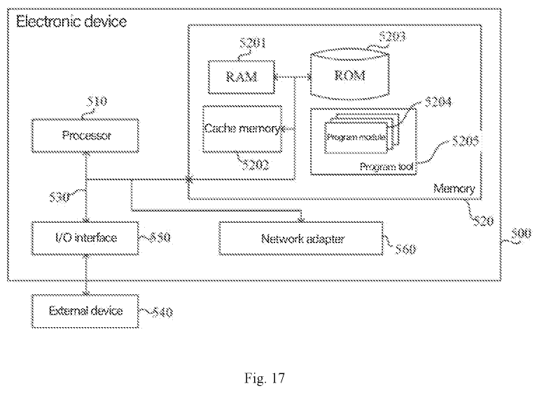

As shown in FIG. 17, the present invention also provides a structural diagram of an electronic device, showing an electronic device 500 for implementing the above-described statement block encapsulation solution, where the electronic device 500 is merely an example and should not be construed as limiting the scope of function and use of embodiments of the present invention.

As shown in FIG. 17, in the electronic device 500, it may include at least one processor 510; and a memory 520 communicatively connected with the at least one processor; wherein

The memory 520 stores instructions executable by the at least one processor 510 to enable the at least one processor 510 for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

It should be noted that the electronic device 500 may be embodied in the form of a general purpose computing device, such as a server device.

In implementation, the components of the electronic device 500 may include, but are not limited to the at least one processor 510, the at least one memory 520, and a bus 530 connecting the various system components including the memory 520 and the processor 510, where the bus 530 may include a data bus, an address bus, and a control bus.

In implementation, the memory 520 may include a volatile memory, such as a random access memory (RAM) 5201 and/or a cache memory 5202, and may further include a read only memory (ROM) 5203.

The memory 520 may also include a program tool 5205 having a set of (at least one) program modules 5204, such program modules 5204 including, but not limited to an operating system, one or more application programs, other program modules, and program data. Each of these examples, or some combination thereof, may include an implementation of a network environment.

The processor 510 executes various functional applications and data processing by executing computer programs stored in the memory 520.

The electronic device 500 may also communicate with one or more external devices 540 (e.g. keyboards, pointing devices, etc.). Such communication may occur through an input/output (I/O) interface 550. Also, the electronic device 500 may communicate with one or more networks (e.g., LAN, WAN, and/or public networks such as the Internet) via a network adapter 560, which communicates with other modules in the electronic device 500 over the bus 530. It should be understood that although not shown, other hardware and/or software modules may be used in conjunction with the electronic device 500, including but not limited to microcode, device drivers, redundant processors, external disk drive arrays, RAID (disk array) systems, tape drives, and data backup storage systems, etc.

It should be noted that while a plurality of units/modules or sub-units/modules of an electronic device have been mentioned above in the detailed description, such division is merely exemplary and not mandatory. Indeed, the features and functions of two or more units/modules described above may be embodied in one unit/module in accordance with embodiments of the present application. Conversely, the features and functions of one unit/module described above may be further divided for embodying by a plurality of units/modules.

Based on the same inventive concept, an embodiment of the present description provides a computer storage medium for statement block encapsulation. The computer storage medium stores computer-executable instructions configured for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of: if the black box signal exists in an external port signal in the current processing module, abandoning processing on the current processing module, and using a parent module instantiating the current processing module as a new current processing module for processing; if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module; if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

Note that the computer storage medium can include, but are not limited to a portable disk, a hard disk, a random access memory, a read-only memory, a erasable programmable read-only memory, an optical storage device, a magnetic storage device, or any suitable combination of the above.

In a possible embodiment, the invention may also provide that the data processing is implemented in the form of a program product including program code for causing a terminal device to perform several steps of a method according to any of the preceding embodiments, when the program product is run on a terminal device.

The program code for performing the present invention may be written in any combination of one or more programming languages, and may be executed entirely on the user device, partly on the user device, as a stand-alone software package, partly on the user device and partly on a remote device, or entirely on the remote device.

Each embodiment of the present description is described in a progressive manner with reference to the same or similar parts throughout the various embodiments, and each embodiment is intended to cover variations from the other embodiments. In particular, for the embodiment of the product to be described later, since it corresponds to the method, the description is relatively simple, and it is sufficient to refer to part of the description of the embodiment of the method.

The applicant states that the description above is only a specific embodiment of the present application, but the scope of protection of the present application is not limited thereto. Any changes and substitutions which can be easily made by those skilled in the art within the technical scope of the present application disclosed are included in the scope of protection the present application. Accordingly, the scope of protection of this application should be determined with reference to the claims.

1. A statement block encapsulation method, characterized by comprising:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of:
if the black box signal exists in an external port signal in the current processing module, abandoning processing on the current processing module, and using a parent module instantiating the current processing module as a new current processing module for processing;
if statement blocks and/or sub-modules in the current processing module comprises a black box signal, clustering and encapsulating the statement blocks and/or sub-modules comprising the same black box signal in the current processing module to be a first module, and instantiating and updating the first module into the current processing module so as to correspondingly replace the statement blocks and/or sub-modules comprising the same black box signal in the current processing module;
if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

2. The statement block encapsulation method according to claim 1, characterized in that before the determining, according to the segmentation boundary, statement blocks to be encapsulated, the statement block encapsulation method further comprises:
reading design code into a memory; and
generating a syntax instance tree corresponding to the design code in the memory.

3. The statement block encapsulation method according to claim 2, characterized in that the traversing each statement block to be encapsulated comprises traversing each statement block to be encapsulated by the syntax instance tree.

4. The statement block encapsulation method according to claim 1, characterized in that the scanning the current processing module and determining whether the current processing module comprises a black box signal comprises:
traversing an external port signal of the current processing module; and
if the external port signal does not comprise the black box signal, scanning whether each statement block and/or sub-module in the current processing module comprises the black box signal.

5. The statement block encapsulation method according to claim 4, characterized in that the statement block encapsulation method further comprises:
establishing a black box signal queue; and
storing queue element information corresponding to the black box signal into the black box signal queue, wherein the queue element information is used for characterizing signal attributes of the black box signal in the statement blocks and/or sub-modules.

6. The statement block encapsulation method according to claim 5, characterized in that the structure of the black box signal queue comprises a first-in-first-out queue structure.

7. The statement block encapsulation method according to claim 5, characterized in that the clustering and encapsulating the statement blocks and/or sub-modules comprising the same black box signal in the current processing module to be a first module comprises:
traversing each piece of queue element information in the black box signal queue, and in the traversal, with regard to the current queue element information, executing the steps of:
searching each of the statement blocks and/or sub-modules in the current processing module;
collecting the statement blocks and/or sub-modules comprising the current queue element information as statement items; and
subjecting the collected statement items to a merging operation.

8. The statement block encapsulation method according to claim 7, characterized in that the subjecting the collected statement items to a merging operation comprises:
performing the merging operation on the collected statement items according to pairwise statement items to form a third module; and
instantiating the third module into the current processing module to replace the pairwise statement items prior to the merging.

9. The statement block encapsulation method according to claim 7, characterized in that the statement block encapsulation method further comprises:
judging whether the statement item of the merging operation is a segmentation boundary;
if so, generating first prompt information which is used for merging the segmentation boundary of the statement item characterizing the merging operation with other statement items.

10. The statement block encapsulation method according to claim 7, characterized in that the statement block encapsulation method further comprises:
storing an operation record for each merging operation in a stack data structure, the operation record including an object, an action, and port information for the merging operation.

11. The statement block encapsulation method according to claim 10, characterized in that the stack data structure comprises a first-in-last-out data structure.

12. The statement block encapsulation method according to claim 11, characterized in that the statement block encapsulation method further comprises:
in the phase of hypergraph transition to RTL, popping operation records in the stack data structure in turn, and restoring the original design code logic by a reverse operation.

13. The statement block encapsulation method according to claim 1, characterized in that after the encapsulating, according to the extracted port information, the statement block to be encapsulated to be a second module, the statement block encapsulation method further comprises:
marking the statement block to be encapsulated which has been encapsulated to be the second module.

14. The statement block encapsulation method according to claim 1, characterized in that when the black box signal exists in an external port signal in the current processing module, the statement block encapsulation method further comprises:
generating second prompt information, wherein the second prompt information is used for characterizing moving the segmentation boundary to an upper module.

15. A statement block encapsulation apparatus, characterized by comprising:
a determination module configured for determining a plurality of statement blocks to be encapsulated according to a segmentation boundary obtained by an RTL segmentation tool;
a traversal module configured for traversing each statement block to be encapsulated, wherein a module where a current statement block to be encapsulated is located is used as a current processing module;
a merging module configured for scanning the current processing module, determining whether the current processing module comprises a black box signal, and executing the steps of:
if the black box signal exists in an external port signal in the current processing module, abandoning processing on the current processing module, and using a parent module instantiating the current processing module as a new current processing module for processing;
if statement blocks and/or sub-modules in the current processing module comprises a black box signal, clustering and encapsulating the statement blocks and/or sub-modules comprising the same black box signal in the current processing module to be a first module, and instantiating and updating the first module into the current processing module so as to correspondingly replace the statement blocks and/or sub-modules comprising the same black box signal in the current processing module;
if the current processing module does not comprise a black box signal, separately executing the fallowing operations on each statement block to be encapsulated in the current processing module:
scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

16. An electronic device for statement block encapsulation, characterized by comprising:
at least one processor; and a memory communicatively coupled to the at least one processor; wherein the memory stores instructions executable by the at least one processor to enable the at least one processor for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of:
if the black box signal exists in an external port signal in the current processing module, abandoning processing on the current processing module, and using a parent module instantiating the current processing module as a new current processing module for processing;
if statement blocks and/or sub-modules in the current processing module comprises a black box signal, clustering and encapsulating the statement blocks and/or sub-modules comprising the same black box signal in the current processing module to be a first module, and instantiating and updating the first module into the current processing module so as to correspondingly replace the statement blocks and/or sub-modules comprising the same black box signal in the current processing module;
if the current processing module does not comprise a black box signal, separately executing the fallowing operations on each statement block to be encapsulated in the current processing module:
scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.

17. A computer storage medium for statement block encapsulation, characterized in that the computer storage medium stores computer-executable instructions configured for:
determining a plurality of statement blocks to be encapsulated according to a segmentation boundary obtained by an RTL segmentation tool;
traversing each statement block to be encapsulated, wherein a module where a current statement block to be encapsulated is located is used as a current processing module;
scanning the current processing module, determining whether the current processing module comprises a black box signal, and executing the steps of:
if the black box signal exists in an external port signal in the current processing module, abandoning processing on the current processing module, and using a parent module instantiating the current processing module as a new current processing module for processing;
if statement blocks and/or sub-modules in the current processing module comprises a black box signal, clustering and encapsulating the statement blocks and/or the black box signal comprising the same black box signal in the current processing module into a first module, and instantiating and updating the first module into the current processing module so as to correspondingly replace the statement blocks and/or the sub-modules comprising the same black box signal in the current processing module;
if the current processing module does not comprise a black box signal, separately executing the fallowing operations on each statement block to be encapsulated in the current processing module: scanning the statement block to be encapsulated, extracting port information, encapsulating, according to the extracted port information, the statement block to be encapsulated to be a second module, and instantiating and updating the second module into the current processing module so as to replace the statement block to be encapsulated;
wherein the black box signal comprises a signal of a signal type not supported by the RTL segmentation tool.
